(19) United States
(12) Patent Application Publication
(10) Pub. No.: US 2012/0247551 A1
(43) Pub. Date: Oct. 4, 2012

(54) SOLAR CELL MODULE AND METHOD FOR MANUFACTURING THE SAME

(75) Inventors: Jae Hoon KIM, Seoul (KR); In Taek Song, Gyeonggi-do (KR); Sung Koo Kang, Gyeonggi-do (KR)

(73) Assignee: SAMSUNG ELECTRO-MECHANICS CO., LTD.

(21) Appl. No.: 13/412,154

(22) Filed: Mar. 5, 2012

(30) Foreign Application Priority Data
Apr. 4, 2011 (KR) 10-2011-0030679

(51) Int. Cl. H01L 31/0216; H01L 31/18

(52) U.S. Cl. 136/256; 438/57; 257/E31.119

(57) ABSTRACT

Disclosed herein are a solar cell module and a method for manufacturing the same. According to an exemplary embodiment of the present invention, there is provided a solar cell module, including: a solar cell having electrode patterns formed on at least one surface thereof; and a parylene coating layer(s) forming a light transmissive passivation layer on at least a front surface of the solar cell. According to another exemplary embodiment of the present invention, there is provided a method for manufacturing a solar cell module, including: (a) preparing a solar cell having electrode patterns formed on at least one surface thereof; and (b) forming a light transmissive passivation layer by coating parylene on at least a front surface of the solar cell.

### CROSS REFERENCE(S) TO RELATED APPLICATIONS

This application claims the benefit under 35 U.S.C. Section 119 of Korean Patent Application Serial No. 10-2011-0030679, entitled “Solar Cell Module and Method for Manufacturing the Same” filed on Apr. 4, 2011, which is hereby incorporated by reference in its entirety into this application.

### BACKGROUND OF THE INVENTION

1. Technical Field

The present invention relates to a solar cell module and a method for manufacturing the same. In particular, the present invention relates to a solar cell module improved by performing normal temperature coating so as to prevent warpage from occurring due to heat fusion during a process of manufacturing a solar cell module and a method for manufacturing the same.

2. Description of the Related Art

Recently, research and development of a solar cell as clean energy source has actively progressed due to an increase in oil price, depletion of fossil fuels, environmental problems, or the like. Application fields of the solar cell have also been widely applied from power generation to general electronic devices. Solar energy conversion efficiency has considerably improved due to the development of technology and as a result, in a laboratory, a high efficiency cell of 23% or more has been developed.

The solar cell is a device that converts light energy into electric energy using a photoelectric effect or a photovoltaic effect. The solar cell is classified into a silicon solar cell, a thin film solar cell, a dye sensitized solar cell, an organic polymer solar cell, or the like, according to the structure material thereof. Today, a silicon solar cell dominates the market. The silicon solar cell is generally configured of a semiconductor in which a p-n junction is made. Further, a solar cell module is formed by connecting the solar cells in parallel or in series according to required electric capacity.

A silicon substrate type (a single crystalline or polycrystalline silicon substrate) solar cell according to the related art generally has a front and rear contact structure according to a contact structure. A method for manufacturing a solar cell module according to the related art uses a chip on board (COB) type.

The process of manufacturing a solar cell module according to the related art will be described with reference to FIG. 9. FIG. 9 shows a schematic flow of the method for manufacturing a solar cell module according to the related art. FIG. 10 is a photograph showing a change in the solar cell due to the heat fusion of EVA resin according to the method for manufacturing a solar cell module according to the related art.

Referring to FIG. 9, the method for manufacturing a solar cell module includes dicing a solar cell in a unit cell, die-attach-bonds the unit cell of the diced solar cell to a printed circuit board (PCB) by a conductive epoxy bond, and performing coating by molding the unit cell with a transparent resin or heat-fusing the unit cell with a polymer material. In this case, as the transparent resin or the polymer material, general ethylene vinyl acetate (EVA) is mainly used.

The EVA is a polymer having excellent transparency, flexibility, adhesion, weather resistance, or the like. The EVA is colorless and transparent when heat is applied thereto and thus, reduces sunlight loss of the solar cell and has excellent water resistance, ultraviolet barrier property when the EVA is used, such that the EVA is used as an encapsulant most appropriate for the solar cell module. However, the EVA needs to be heat-fused at a temperature of about 150° C. or more so as to obtain necessary crosslink density.

### SUMMARY OF THE INVENTION

When the heat fusion is performed at about 150° C. as in the related art, in a solar cell, a warpage occurs due to a difference in thermal expansion coefficients and a warpage of PCB occurs as a whole. FIG. 10 is a photograph showing the warpage of the solar cell when the EVA resin is heat-fused at 80° C. according to the manufacturing method of related art. As shown in FIG. 10, it can be confirmed that the solar cell is bent due to the warpage thereof. In particular, when the solar cell that is subjected to the warpage phenomenon is pressed by a front cover glass, or the like, in a post process, an electrode wiring or a rear contact may be broken.

In particular, as the thickness of the solar cell becomes gradually thin according to the manufacturing of the small solar cell, the problem of the warpage due to the process of the related art may become more serious.

An object of the present invention is to provide a solar cell module capable of previously preventing a warpage of a solar cell due to heat fusion by performing normal temperature coating using parylene mainly used for an aerospace field and a method for manufacturing the same.

According to an exemplary embodiment of the present invention, there is provided a solar cell module, including: a solar cell having electrode patterns formed on at least one surface thereof; and a parylene coating layer(s) forming a light transmissive passivation layer on at least a front surface of the solar cell.

The solar cell may be a rear contact solar cell having the electrode patterns formed on a rear surface thereof.

A top portion of the parylene coating layer may be provided with a front cover layer.

A bottom portion of the solar cell may be coupled with a PCB.

The parylene coating layer may be formed on the front surface of the solar cell and a bottom portion of the PCB respectively, and a bottom portion of the parylene coating layer formed on the bottom portion of the PCB may be provided with a back sheet.

The parylene coating layers may be formed on the front and rear surfaces of the solar cell respectively, and a back sheet may be formed on a bottom portion of the parylene coating layers formed on the rear surface of the solar cell.

The solar cell may be a silicon semiconductor solar cell.

The parylene coating layer may be deposited and coated at normal temperature using at least one parylene dimer selected from parylene N, parylene C, parylene D, and parylene F.

According to an exemplary embodiment of the present invention, there is provided a method for manufacturing a solar cell module, including: (a) preparing a solar cell having electrode patterns formed on at least one surface thereof; and (b) forming a light transmissive passivation layer by coating parylene on at least a front surface of the solar cell.

The method for manufacturing a solar cell module may further include (c) forming a front cover layer on a top portion of the parylene passivation layer formed on a front surface of the solar cell.

The solar cell prepared at the step (a) may have a PCB bonded to a bottom portion thereof.

The method for manufacturing a solar cell module may further include (d) forming a back sheet on a bottom portion of the parylene passivation layer formed on the bottom portion of the solar cell, wherein at the step (b) the top front surface and the bottom portion of the solar cell are coated with parylene.

The step (b) may include: (i) masking portions of the electrode patterns on a surface of the solar cell on which the parylene coating is performed using a masking tape; (ii) performing the parylene coating on the masked solar cell; and (iii) removing the masking tape after the parylene coating.

At the step (b), parylene deposition coating may be performed using at least one parylene dimer selected from parylene N, parylene C, parylene D, and parylene F.

The step (b) may include: (b-1) putting the at least one parylene dimer in a vaporizer to be evaporated in a gas phase at 120 to 180° C.; (b-2) converting the parylene dimer evaporated at the step (b-1) into a monomer through a pyrolysis heated at 650 to 700° C.; and (b-3) depositing and coating the parylene dimer converted into the monomer at the step (b-2) on the solar cell at normal temperature in a deposition chamber.

### BRIEF DESCRIPTION OF THE DRAWINGS

FIG. 1 is a diagram schematically showing a cross section of a solar cell module according to an exemplary embodiment of the present invention;

FIG. 2 is a diagram schematically showing a cross section of a solar cell module according to another exemplary embodiment of the present invention;

FIG. 3 is a flow chart schematically showing a method for manufacturing a solar cell module according to an exemplary embodiment of the present invention; and

FIG. 4 is a flow chart schematically showing a method for manufacturing a solar cell module according to another exemplary embodiment of the present invention;

FIG. 5 is a flow chart schematically showing a method for manufacturing a solar cell module according to another exemplary embodiment of the present invention;

FIG. 6 is a flow chart schematically showing a process of coating parylene of a method for manufacturing a solar cell module according to an exemplary embodiment of the present invention;

FIG. 7 is a flow chart schematically showing a process of coating parylene of a method for manufacturing a solar cell module according to another exemplary embodiment of the present invention;

FIG. 8 is a graph showing an I-V curved line according to an I-V test before and after the parylene coating according to the exemplary embodiment of the present invention;

FIG. 9 is a flow chart schematically showing a method for manufacturing a solar cell module according to the related art; and

FIG. 10 is a photograph showing a change in the solar cell due to the heat fusion of EVA resin according to the method for manufacturing a solar cell module according to the related art.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

It will be understood that when an element is referred to as simply being “coupled to” or “connected to” another element rather than being “directly coupled to” or “directly connected to” another element in the present description, it can be directly connected with the other element or may be connected with another element, having other element coupled or connected therebetween, as long as it is not contradictory to the description or is opposite to the concept of the present invention.

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

The present invention relates to a solar cell module and a method for manufacturing the same, and more particularly, can simplify a manufacturing process and improve characteristics of a solar cell using parylene.

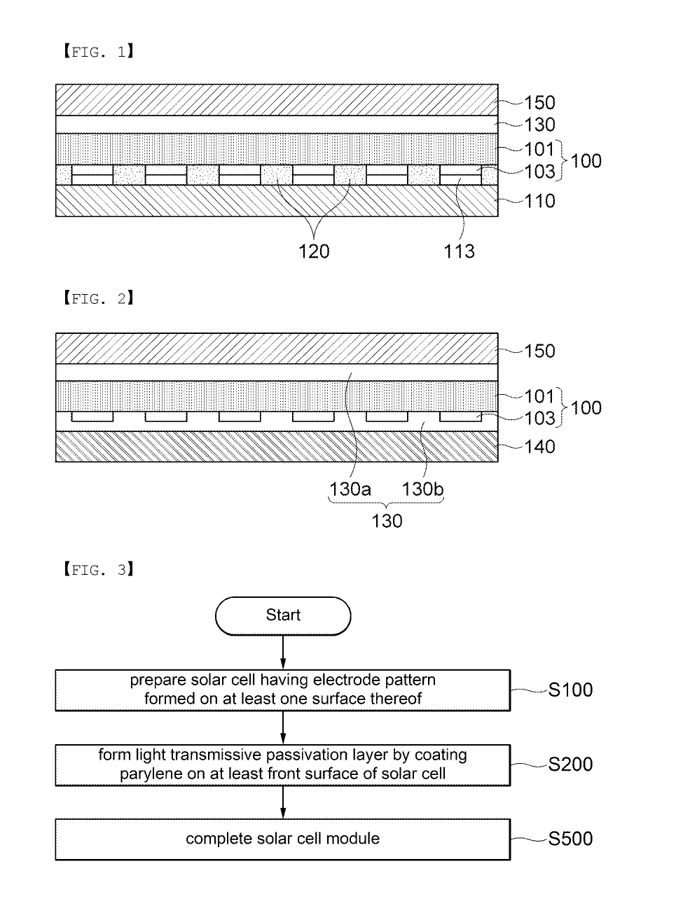

FIG. 1 is a diagram schematically showing a cross section of a solar cell module according to an exemplary embodiment of the present invention and FIG. 2 is a diagram schematically showing a cross section of a solar cell module according to another exemplary embodiment of the present invention.

FIG. 1 shows a solar cell module in which parylene is coated on a front surface of a solar cell 100 by bonding the solar cell 100 to a PCB 110 and a front cover layer 150 such as a transparent cover sheet or a front cover glass is formed on a parylene coating layer 130 and FIG. 2 shows a solar cell module in which parylene coating layers 130a and 130b are formed on the front and rear surfaces on the solar cell 100 and the front cover layer 150 is disposed on the front parylene coating layer 130a and a back sheet 140 is disposed below the rear parylene coating layer 130b. FIGS. 1 and 2 are diagrams showing an example of the exemplary embodiments of the present invention and the exemplary embodiments of the present invention are not to be construed as being limited to ones shown in FIGS. 1 and 2 In FIGS. 1 and 2, reference numeral 101 is a semiconductor layer, for example, a silicon semiconductor layer, and reference numeral 103 is a electrode pattern of a solar cell. In FIG. 2, reference numeral 103 is an electrode pattern on the PCB 110.

Referring to FIGS. 1 or/and 2, the solar cell module according to the exemplary embodiment of the present invention includes the solar cell 100 having the electrode pattern 103 formed on at least one surface thereof and the parylene coating layer 130 (130a and 130b) formed on at least the front surface of the solar cell 100.

If the electrode patterns 103 are formed on at least one surface of the front and rear surfaces of the solar cell 100, the solar cell according to the exemplary embodiment of the present invention may be enough. Preferably, describing another exemplary embodiment of the present invention with reference to FIG. 1, the solar cell 100, which is a rear contact solar cell, has the electrode pattern 103 formed on the rear surface thereof. Although not shown, in another exemplary embodiment of the present invention, the electrode patterns may be formed on the rear and front surfaces of the solar cell.

The solar cell 100 may be a silicon solar cell and may be other solar cells. Preferably, according to the exemplary embodiment of the present invention, the solar cell 100 is a silicon semiconductor solar cell. A configuration of the solar cell is well known in the art in advance and therefore, the detailed description thereof will be omitted.

In the exemplary embodiment of the present invention, the solar cell module includes the parylene coating layer 130 (130a and 130b) coated on at least the front surface of the solar cell 100. The parylene coating layer 130 has light transmission and forms a passivation layer.

The parylene means unique collection of thermoplastic polymers that are formed on a surface exposed to fine gas in a vacuum state. The parylene has excellent insulation, water resistance, corrosion resistance, and chemical resistance and application fields thereof are wide. A Cu electrode generally used in the solar cell is easily oxidized and therefore, needs to be provided with a passivation layer so as to prevent external air from permeating into the solar cell. The parylene coating layer has an excellent passivation function and an excellent anti-oxidation function of the metal electrode.

In addition, the parylene may easily control the coating thickness from several μm to several hundreds of μm unlike the liquid phase coating and may be coated on the overall area of the solar cell product at the uniform thickness. Therefore, when performing the parylene coating, the thinness of the solar cell module may be implemented.

Further, the parylene coating provides a smooth surface, such that foreign materials may not be easily stuck and the adhered foreign materials may be easily removed. Therefore, the manufacturing process may be simplified since there is no need to perform separate works to remove foreign materials or the foreign materials may be easily removed.

Preferably, according to the exemplary embodiment of the present invention, the parylene coating layer 130 (130a and 130b) is deposited and coated at normal temperature using at least one parylene dimer selected from parylene N (Di-Para-Xylylene), parylene C (Di-Chloro-Xylylene), parylene D (Tetra-Chloro-Xylylene), and parylene (Octafluoro-[2,2]para-Cyclophane). In this case, as the usable parylene dimer, any one or a selective mixture thereof may be used. The normal temperature deposition coating of the parylene will be described in detail in the description of the method for manufacturing a solar cell module.

Although the exemplary embodiment of the present invention does not show the parylene coating layer, the parylene coating layer may be used as a surface or may be used as an interface layer between the front cover glass, or the like, and the solar cell 100. When the parylene coating layer is used as the surface of the solar cell module, it serves as a water repellent layer.

Preferably, describing another exemplary embodiment of the present invention with reference to FIGS. 1 or/and 2, the front cover layer 150 is formed on the top portion of the parylene coating layers 130 (130a). The front cover layer 150 is formed using a transparent resin sheet, a front cover glass, or the like.

In addition, describing another exemplary embodiment of the present invention with reference to FIG. 1, preferably, the PCB 110 is coupled with the bottom portion of the solar cell 100. As shown in FIG. 1, the PCB 110 may be coupled with the bottom portion of the rear contact solar cell 100 and although not shown, the PCB 110 may be coupled with the bottom portion of the solar cell 100 having the electrode pattern 103 formed on the front and rear surfaces thereof. In FIG. 1, reference numeral 120 shows an adhesive layer.

Further, although not shown, according to another exemplary embodiment of the present invention, the parylene coating layer is formed on a lower surface of the PCB 110 that is coupled with both of the front surface of the solar cell 100 and the rear surface of the solar cell 100. Preferably, the back sheet 140 may be formed on the bottom portion of the parylene coating layer that is formed on the bottom portion of the PCB 110. The configuration of the back sheet is a technology configuration well known in the art in advance and the detailed description thereof will be omitted.

Other exemplary embodiments of the present invention will be described in detail with reference to FIG. 2.

Referring to FIG. 2, preferably, the parylene coating layers 130a and 130b are formed on the front and rear surfaces of the solar cell 100. The parylene layer 130b coated on the rear surface of the solar cell 100 sufficiently serves as the passivation. FIG. 2 shows a cross section of the solar cell module in which the positive and negative electrode patterns 103 in a bar type are alternately disposed and the electrode patterns 103 coated by the parylene coating layer 130b may contact the external electrode through edge portions of both sides.

More preferably, referring to FIG. 2, the back sheet 140 is formed on the bottom portion of the parylene coating layer 130b that is formed on the rear surface of the solar cell 100.

Next, a method for manufacturing a solar cell module according to another exemplary embodiment of the present invention will be described with reference to the accompanying drawings. In describing in detail the exemplary embodiment of the present invention, the description of the above-mentioned solar cell module and FIGS. 1 and 2 will be referred.

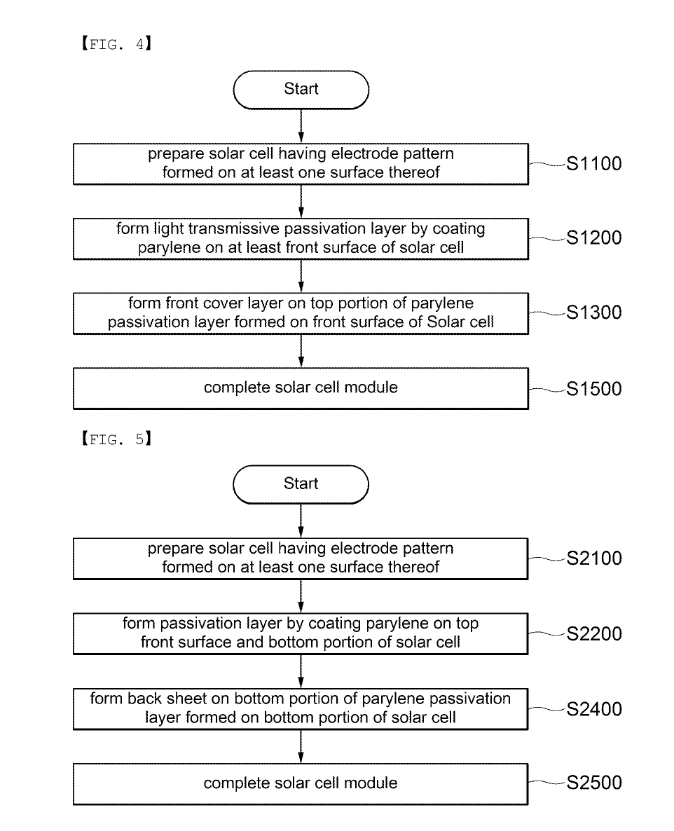

FIG. 3 is a flow chart schematically showing a method for manufacturing a solar cell module according to an exemplary embodiment of the present invention, FIG. 4 is a flow chart schematically showing a method for manufacturing a solar cell module according to another exemplary embodiment of the present invention, and FIG. 5 is a flow chart schematically showing a method for manufacturing a solar cell module according to another exemplary embodiment of the present invention.

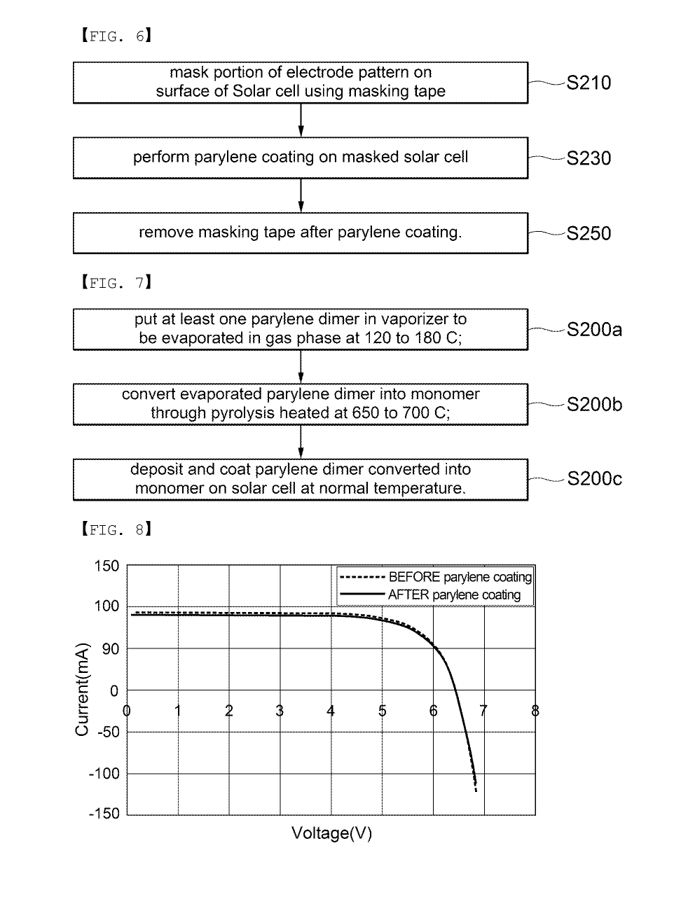

In addition, FIG. 6 is a flow chart schematically showing a process of coating parylene of a method for manufacturing a solar cell module according to an exemplary embodiment of the present invention and FIG. 7 is a flow chart schematically showing a process of coating parylene of a method for manufacturing a solar cell module according to another exemplary embodiment of the present invention.

Referring to FIGS. 3 to 5, an exemplary embodiment of the method for manufacturing a solar cell module according to another exemplary embodiment of the present invention includes the following steps (a) and (b). The solar cell module finally completes through steps (a) and (b) (S500, S1500, and S2500).

First, at step (a) (S100, S1100, and S2100), the solar cell 100 having the electrode pattern 103 formed on at least one surface thereof is prepared. If the electrode pattern 103 is formed on at least one surface of the front and rear surfaces of the prepared solar cell 100, the solar cell according to the exemplary embodiment of the present invention may be enough. Preferably, the solar cell 100 is the rear contact solar cell having the electrode pattern 103 formed on the rear surface thereof, as shown in FIGS. 1 and 2. Alternatively, in another exemplary embodiment of the present invention, the electrode pattern 103 may be formed on the rear and front surfaces of the solar cell.

Preferably, according to another exemplary embodiment of the present invention, the solar cell 100 prepared at step (a) (S100, S1100, and S1200) may have the PCB bonded to the bottom portion thereof, as shown in FIG. 1.

Alternatively, according to another exemplary embodiment of the present invention, preferably, the solar cell 100 may be prepared in a state in which the PCB is not bonded to the rear surface of the solar cell 100 as shown in FIG. 2.

Next, step (b) (S200, S1200, and S2200) will be described. At step (b) (S200, S1200, and S2200), the light transmissive passivation layer is formed by coating the parylene on at least the front surface of the solar cell 100.

Preferably, describing another exemplary embodiment of the present invention with reference to FIG. 5, at step (b), the parylene is coated on the top front surface and the bottom portion of the solar cell 100 (S2200). When the parylene coating is performed on the bottom portion of the solar cell 100, as shown in FIG. 2, the parylene coating may be directly performed on the rear surface of the solar cell 100. Alternatively, referring to FIG. 1, the parylene coating may be performed on the bottom portion of the PCB 110 that is bonded to the rear surface of the solar cell 100, without contacting the rear surface of the solar cell 100. That is, the substrate or other functional layer may be inserted between the solar cell 100 and the bottom parylene coating layer 130.

Preferably, according to another exemplary embodiment of the present invention, in exemplary embodiment of the present invention shown in FIGS. 3 to 5 or exemplary embodiments of the present invention shown in FIGS. 6 and 7, step (b) (S200, S1200, S2200, S230, S200a to S200c), the parylene deposition coating is performed using the at least one parylene dimer selected from the parylene N, the parylene C, the parylene D, and the parylene F.

An exemplary embodiment of the parylene coating method will be described in detail with reference to FIG. 6.

According to the exemplary embodiment of the present invention, referring to FIG. 6, the above-mentioned steps (b) performing the parylene coating include the following steps (i) to (iii) (S210 to S250).

First, at step (i) (S210), the portion of the electrode pattern 103 on the surface of the solar cell on which the parylene is coated is masked using a masking tape. When the surface on which the parylene is coated is provided with the electrode pattern 103, the masking is performed on the electrode portion. As shown in FIG. 2, even when the parylene is coated on the rear surface of the rear contact solar cell 100, the electrode portion electrically connected to the external electrode is masked using the masking tape. The masking process is well known in the semiconductor technology field.

Next, at step (ii) (S230), the parylene is coated on the masked solar cell 100. The detailed description of the parylene coating refers to the above description or the following description.

Further, at step (iii) (S250), the masking tape is removed after the parylene coating.

The detailed steps of performing the parylene normal temperature deposition coating according to the exemplary embodiment of the present invention will be described with reference to FIG. 7.

According to another exemplary embodiment of the present invention, referring to FIG. 7, step (b) (S200, S1200, and S2200) in FIGS. 3 to 5 as described above or step (b) in FIG. 6, in detail, step (ii) (S230) includes the following steps (b-1) to (b-3) (S200a to S200c). Preferably, the parylene coating uses a chemical vapor deposition (CVD). The chemical vapor deposition (CVD) system is configured to include three components, that is, a vaporizer, a pyrolysis, and a deposition chamber.

At step (b-1) (S200a), at least one parylene dimer is put in the vaporizer and is evaporated in a gas phase at 120 to 180° C. For example, the parylene dimer is put in the vaporizer in a powder type by one or a combination of at least two selected from the parylene N, the parylene C, the parylene D, and the parylene F.

At the following step (b-2) (S200b), the parylene dimer evaporated at the above-mentioned step (b-1) (S200a) is converted into a monomer through the pyrolysis heated at 650 to 700° C.

Further, at step (b-3) (S200c), the parylene dimer converted into the monomer at the above-mentioned step (b-2) (S200b) is deposited and coated on the solar cell 100 at normal temperature in the deposition chamber. For example, a poly-para-Xylylene film is coated on the front surface of the solar cell module in a polymer type in the vacuum chamber of normal temperature.

The parylene deposition coating method is well known to those skilled in the art in the coating field and the additional description thereof will be omitted.

Next, another exemplary embodiment of the present invention will be described with reference to FIG. 4.

Referring to FIG. 4, in another exemplary embodiment of the present invention, the method for manufacturing a solar cell module includes step (c) (S1300) forming the front cover layer 150. Referring to FIGS. 1, 2, and 4, the front cover layer 150 is formed on the top portion of the parylene passivation layer 130 (130a) formed on the front surface of the solar cell 100.

Further, describing another exemplary embodiment of the present invention with reference to FIG. 5, the method for manufacturing a solar cell module according to the exemplary embodiment of the present invention includes step (d) (S2400) forming the back sheet 140. The back sheet 140 is formed on the bottom portion of the parylene passivation layer 130b that is formed on the bottom portion of the solar cell 100. In this configuration, an intermediate medium is not present between the parylene passivation layer 130b on which the back sheet is formed and the solar cell 100 or, for example, the PCB 110 of FIG. 1 or other functional layers may be included as the intermediate medium.

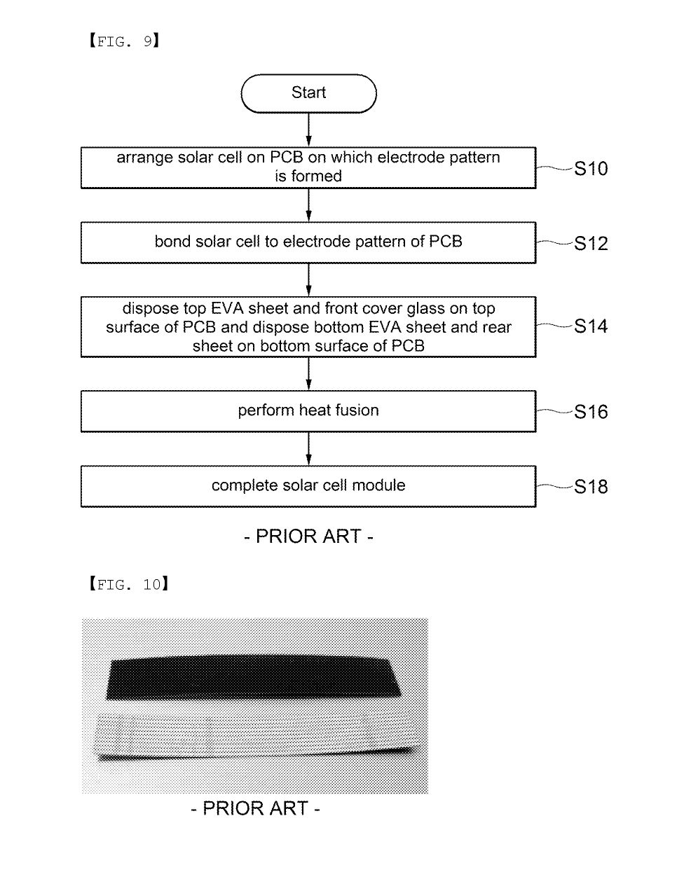

Next, the characteristics of the solar cell before and after the parylene coating of the solar cell module on which the parylene is coated according to the exemplary embodiment of the present invention will be described with reference to FIG. 8.

FIG. 8 is a graph showing an I-V curved line according to an I-V test before and after the parylene coating according to the exemplary embodiment of the present invention.

In addition, the following [Table 1] shows I-V test results before and after the parylene coating.

TABLE 1

| | | Before | After |
|---|---|---|---|
| Division | Unit | Parylene Coating | Parylene Coating |
| Voc | V | 6.42 | 6.45 |
| Isc | mA | 93.50 | 90.63 |
| Jsc | mA/cm² | 3.90 | 3.78 |
| Fill Factor | % | 71.79 | 72.67 |
| Imax | mA | 82.45 | 79.98 |
| Vmax | V | 5.22 | 5.31 |
| Pmax | mW | 430.63 | 424.63 |
| Efficiency | % | 17.94 | 17.69 |
| R shunt | ohm | 4432.08 | 6071.51 |
| R series | ohm | 5.62 | 5.64 |

[Table 1] and FIG. 8 both show the I-V performance test results before and after the parylene coating. Referring to [Table 1] and FIG. 8, it can be appreciated that the difference in Imax, Vmax, and Pmax before and after the parylene is coated is insignificant and the difference in Efficiency showing conversion efficiency is insignificant. That is, even after the parylene is coated, it can be appreciated that similar results that there is little degradation in light transmittance are shown.

As set forth above, the exemplary embodiment of the present invention provides the solar cell module performing the normal temperature coating using the parylene having the excellent insulation, water repellency, corrosion resistance, and chemical resistance and the method for manufacturing the same, thereby making it possible to previously prevent the warpage of the solar cell due to the heat fusion.

In addition, the exemplary embodiment of the present invention can simplify the manufacturing process and lower the thickness of the solar cell module while solving the problem of warpage due to heat generated at the time of heat-fusing the encapsulant using the normal temperature process.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. While this invention has been described in connection with what is presently considered to be practical exemplary embodiments, it is to be understood that the invention is not limited to the disclosed embodiments. Therefore, it will be apparent to those skilled in the art that various modifications, substitutions and equivalents can be made in the present invention without departing from the spirit or scope of the inventions.

What is claimed is:

1. A solar cell module, comprising:
a solar cell having electrode patterns formed on at least one surface thereof; and
a parylene coating layer(s) forming a light transmissive passivation layer on at least a front surface of the solar cell.

2. The solar cell module according to claim 1, wherein the solar cell is a rear contact solar cell having the electrode patterns formed on a rear surface thereof.

3. The solar cell module according to claim 1, wherein a top portion of the parylene coating layer is provided with a front cover layer.

4. The solar cell module according to claim 1, wherein a bottom portion of the solar cell is coupled with a PCB.

5. The solar cell module according to claim 4, wherein the parylene coating layers are formed on the front surface of the solar cell and a bottom portion of the PCB respectively, and a bottom portion of the parylene coating layer formed on the bottom portion of the PCB is provided with a back sheet.

6. The solar cell module according to claim 1, wherein the parylene coating layers are formed on the front and rear surfaces of the solar cell respectively, and
a back sheet is formed on a bottom portion of the parylene coating layers formed on the rear surface of the solar cell.

7. The solar cell module according to claim 1, wherein the solar cell is a silicon semiconductor solar cell.

8. The solar cell module according to claim 1, wherein the parylene coating layer(s) is deposited and coated at normal temperature using at least one parylene dimer selected from parylene N, parylene C, parylene D, and parylene F.

9. The solar cell module according to claim 2, wherein the parylene coating layer(s) is deposited and coated at normal temperature using at least one parylene dimer selected from parylene N, parylene C, parylene D, and parylene F.

10. The solar cell module according to claim 5, wherein the parylene coating layers are deposited and coated at normal temperature using at least one parylene dimer selected from parylene N, parylene C, parylene D, and parylene F.

11. The solar cell module according to claim 6, wherein the parylene coating layers are deposited and coated at normal temperature using at least one parylene dimer selected from parylene N, parylene C, parylene D, and parylene F.

12. A method for manufacturing a solar cell module, comprising:
(a) preparing a solar cell having electrode patterns formed on at least one surface thereof; and
(b) forming a light transmissive passivation layer by coating parylene on at least a front surface of the solar cell.

13. The method according to claim 12, further comprising:
(c) forming a front cover layer on a top portion of the parylene passivation layer formed on a front surface of the solar cell.

14. The method according to claim 12, wherein the solar cell prepared at the step (a) has a PCB bonded to a bottom portion thereof.

15. The method according to claim 12, further comprising:
(d) forming a back sheet on a bottom portion of the parylene passivation layer formed on the bottom portion of the solar cell,
wherein at the step (b) the top front surface and the bottom portion of the solar cell are coated with parylene.

16. The method according to claim 12, wherein the step (b) includes:
(i) masking portions of the electrode patterns on a surface of the solar cell on which the parylene coating is performed using a masking tape;
(ii) performing the parylene coating on the masked solar cell; and
(iii) removing the masking tape after the parylene coating.

17. The method according to claim 12, wherein at the step (b), parylene deposition coating is performed using at least one parylene dimer selected from parylene N, parylene C, parylene D, and parylene F.

18. The method according to claim 15, wherein at the step (b), parylene deposition coating is performed using at least one parylene dimer selected from parylene N, parylene C, parylene D, and parylene F.

19. The method according to claim 17, wherein the step (b) includes:
(b-1) putting the at least one parylene dimer in a vaporizer to be evaporated in a gas phase at 120 to 180° C.;
(b-2) converting the parylene dimer evaporated at the step (b-1) into a monomer through a pyrolysis heated at 650 to 700° C.; and
(b-3) depositing and coating the parylene dimer converted into the monomer at the step (b-2) on the solar cell at normal temperature in a deposition chamber.
